(19) United States
(12) Patent Application Publication
(10) Pub. No.: US 2024/0071952 A1
(43) Pub. Date: Feb. 29, 2024

(54) INTEGRATED CIRCUIT DEVICE AND METHOD OF FORMING THE SAME

(71) Applicant: Taiwan Semiconductor Manufacturing Co., Ltd., Hsinchu (TW)

(72) Inventors: Chih-Chiang Tsao, Taoyuan (TW); Hsuan-Ting Kuo, Taichung (TW); Chao-Wei Chiu, Hsinchu (TW); Hsiu-Jen Lin, Zhubei (TW); Ching-Hua Hsieh, Hsinchu (TW)

(21) Appl. No.: 18/152,502

(22) Filed: Jan. 10, 2023

Related U.S. Application Data
(60) Provisional application No. 63/374,026, filed on Aug. 31, 2022.

(51) Int. Cl. H01L 23/00; H01L 21/48; H01L 21/56; H01L 21/683; H01L 23/31; H01L 23/538; H01L 25/00; H01L 25/10

(52) U.S. Cl. CPC H01L 23/562; H01L 21/4853; H01L 21/4857; H01L 21/565; H01L 21/568; H01L 21/6835; H01L 23/3128; H01L 23/5383; H01L 23/5386; H01L 23/5389; H01L 24/08; H01L 24/19; H01L 24/20; H01L 24/72; H01L 24/73; H01L 24/81; H01L 24/90; H01L 24/92; H01L 25/105; H01L 25/50; H01L 2221/68372; H01L 2224/16227; H01L 2224/214; H01L 2224/81011; H01L 2224/81815; H01L 2224/92122; H01L 2225/1035; H01L 2225/1058; H01L 2924/1427; H01L 2924/3511

(57) ABSTRACT

A method includes depositing solder paste over first contact pads of a first package component. Spring connectors of a second package component are aligned to the solder paste. The solder paste is reflowed to electrically and physically couple the spring connectors of the second package component to the first contact pads of the first package component. A device includes a first package component and a second package component electrically and physically coupled to the first package component by way of a plurality of spring coils. Each of the plurality of spring coils extends from the first package component to the second package component.

### PRIORITY CLAIM AND CROSS-REFERENCE

This application claims the benefit of U.S. Provisional Application No. 63/374,026, filed on Aug. 31, 2022, which application is hereby incorporated herein by reference.

### BACKGROUND

In integrated circuits, some circuit components such as System-On-Chip (SOC) dies, System-On-Wafer (SOW) structures, and Central Processing Units (CPU) have large coefficient of thermal expansion (CTE) mismatch, which can cause joint stress and/or warpage between stacked substrates.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of an integrated circuit die in accordance with some embodiments.

FIGS. 2 through 12A and 12B illustrate cross-sectional and top-down views of intermediate steps during a process for forming a package component, in accordance with some embodiments.

FIGS. 13A, 13B, 13C, and 13D illustrate various cross-sectional views of intermediate steps during a process for preparing a second package component including spring coils, in accordance with some embodiments.

FIGS. 14, 15A, 15B, 15A′, 15B′, 15A″, 15B″, 15A″′, 15B″′, and 16 illustrate cross-sectional and top-down views of intermediate steps and variations thereof during a process for attaching a second package component to a first package component using spring coils, in accordance with some embodiments.

FIGS. 17A, 17B, 17C, 17D, 18A, 18B, 18C, and 18D illustrate close up views of spring coils, in accordance with some embodiments.

FIGS. 19 and 20 illustrate cross-sectional views of intermediate steps during a process for forming a package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, to relieve stress caused by mismatch between the coefficient of thermal expansion (CTE) of a first device and the CTE of a second device, coil springs (e.g., microsprings) are used to join the first device to the second device. The coil springs provide solid physical connection and efficient electrical connection, but also provide the ability to absorb horizontal and vertical stresses which can result from mismatch CTE and/or warpage. In some embodiments, the first device may be a voltage regulator module or other device attached to an integrated fan out (InFO) package.

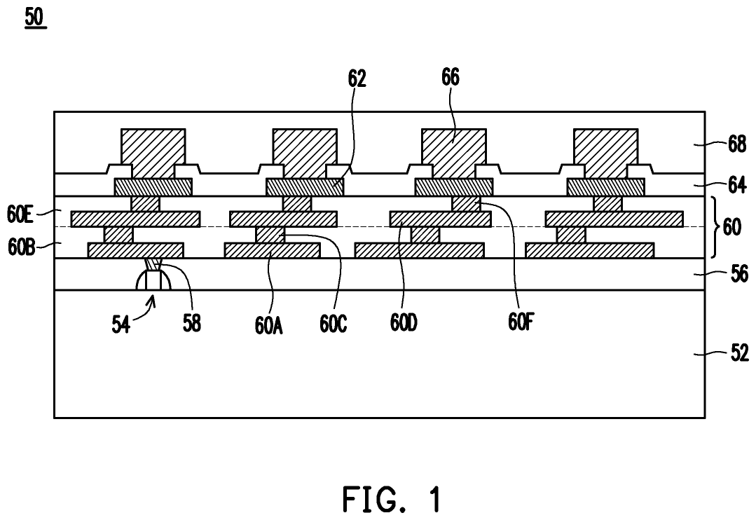

FIG. 1 illustrates a cross-sectional view of an integrated circuit die 50 in accordance with some embodiments. The integrated circuit die 50 will be packaged in subsequent processing to form an integrated circuit package. The integrated circuit die 50 may be a logic die (e.g., central processing unit (CPU), graphics processing unit (GPU), system-on-a-chip (SoC), application processor (AP), microcontroller, etc.), a memory die or cube of memory dies (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlinAs, AlGaAs, GalnAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front side, and an inactive surface (e.g., the surface facing downwards in FIG. 1), sometimes called a back side.

Devices 54 may be formed at the front surface of the semiconductor substrate 52. The devices 54 may be active devices (e.g., transistors, diodes, etc.), capacitors, resistors, etc. An inter-layer dielectric (ILD) 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 58 extend through the ILD 56 to electrically and physically couple the devices 54. For example, when the devices 54 are transistors, the conductive plugs 58 may couple the gates and source/drain regions of the transistors. The conductive plugs 58 may be formed of tungsten, cobalt, nickel, copper, silver, gold, aluminum, the like, or combinations thereof. An interconnect structure 60 is over the ILD 56 and conductive plugs 58. The interconnect structure 60 interconnects the devices 54 to form an integrated circuit. The interconnect structure 60 may be formed by, for example, metallization patterns in dielectric layers on the ILD 56. The metallization patterns include metal lines, such as metal lines 60A and metal lines 60D, and vias, such as vias 60C and vias 60F, formed in one or more low-k dielectric layers, such as dielectric layer 60B and dielectric layer 60E. The metallization patterns of the interconnect structure 60 are electrically coupled to the devices 54 by the conductive plugs 58.

The integrated circuit die 50 further includes pads 62, such as aluminum pads, to which external connections are made. The pads 62 are on the active side of the integrated circuit die 50, such as in and/or on the interconnect structure 60. One or more passivation films 64 are on the integrated circuit die 50, such as on portions of the interconnect structure 60 and pads 62. Openings extend through the passivation films 64 to the pads 62. Die connectors 66, such as conductive pillars (for example, formed of a metal such as copper), extend through the openings in the passivation films 64 and are physically and electrically coupled to respective ones of the pads 62. The die connectors 66 may be formed by, for example, plating, or the like. The die connectors 66 electrically couple the respective integrated circuits of the integrated circuit die 50.

Optionally, solder regions (e.g., solder balls or solder bumps) may be disposed on the pads 62. The solder balls may be used to perform chip probe (CP) testing on the integrated circuit die 50. CP testing may be performed on the integrated circuit die 50 to ascertain whether the integrated circuit die 50 is a known good die (KGD). Thus, only integrated circuit dies 50, which are KGDs, undergo subsequent processing are packaged, and dies, which fail the CP testing, are not packaged. After testing, the solder regions may be removed in subsequent processing steps.

A dielectric layer 68 may (or may not) be on the active side of the integrated circuit die 50, such as on the passivation films 64 and the die connectors 66. The dielectric layer 68 laterally encapsulates the die connectors 66, and the dielectric layer 68 is laterally coterminous with the integrated circuit die 50. Initially, the dielectric layer 68 may bury the die connectors 66, such that the topmost surface of the dielectric layer 68 is above the topmost surfaces of the die connectors 66. In some embodiments where solder regions are disposed on the die connectors 66, the dielectric layer 68 may bury the solder regions as well. Alternatively, the solder regions may be removed prior to forming the dielectric layer 68.

The dielectric layer 68 may be a polymer such as polybenzoxazole (PBO), polyimide, benzocyclobutene (BCB), or the like; a nitride such as silicon nitride or the like; an oxide such as silicon oxide, PSG, BSG, BPSG, or the like; the like, or a combination thereof. The dielectric layer 68 may be formed, for example, by spin coating, lamination, chemical vapor deposition (CVD), or the like. In some embodiments, the die connectors 66 are exposed through the dielectric layer 68 during formation of the integrated circuit die 50. In some embodiments, the die connectors 66 remain buried and are exposed during a subsequent process for packaging the integrated circuit die 50. Exposing the die connectors 66 may remove any solder regions that may be present on the die connectors 66.

In some embodiments, the integrated circuit die 50 is a stacked device that includes multiple semiconductor substrates 52. For example, the integrated circuit die 50 may be a memory device such as a hybrid memory cube (HMC) module, a high bandwidth memory (HBM) module, or the like that includes multiple memory dies. In such embodiments, the integrated circuit die 50 includes multiple semiconductor substrates 52 interconnected by through-substrate vias (TSVs). Each of the semiconductor substrates 52 may (or may not) have an interconnect structure 60.

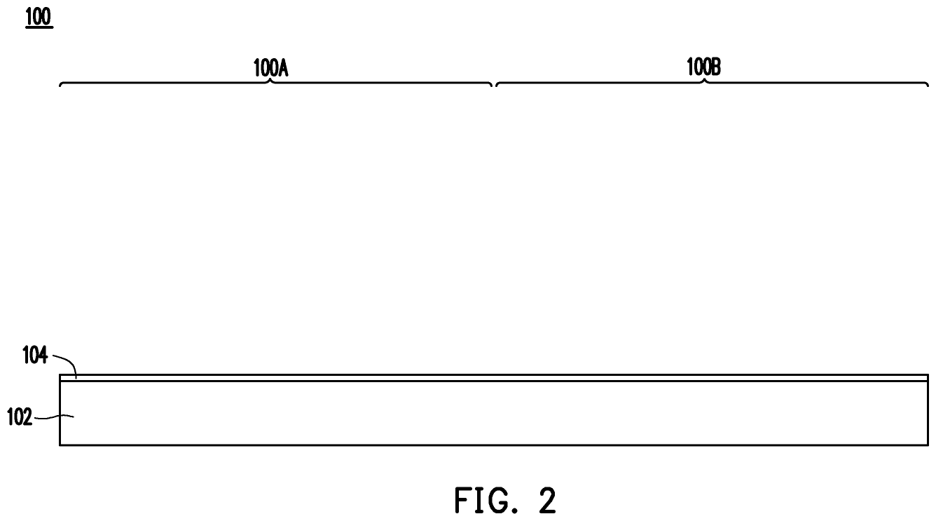

FIGS. 2 through 13 illustrate cross-sectional views of intermediate steps during a process for forming a first package component 100 or workpiece, in accordance with some embodiments. A first package region 100A and a second package region 100B are illustrated, and one or more of the integrated circuit dies 50 are packaged to form an integrated circuit package in each of the package regions 100A and 100B. The integrated circuit packages may also be referred to as integrated fan-out (InFO) packages.

In FIG. 2, a carrier substrate 102 is provided, and a release layer 104 is formed on the carrier substrate 102. The carrier substrate 102 may be a glass carrier substrate, a ceramic carrier substrate, or the like. The carrier substrate 102 may be a wafer, such that multiple packages can be formed on the carrier substrate 102 simultaneously.

The release layer 104 may be formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 104 may be dispensed as a liquid and cured, may be a laminate film laminated onto the carrier substrate 102, or may be the like. The top surface of the release layer 104 may be leveled and may have a high degree of planarity.

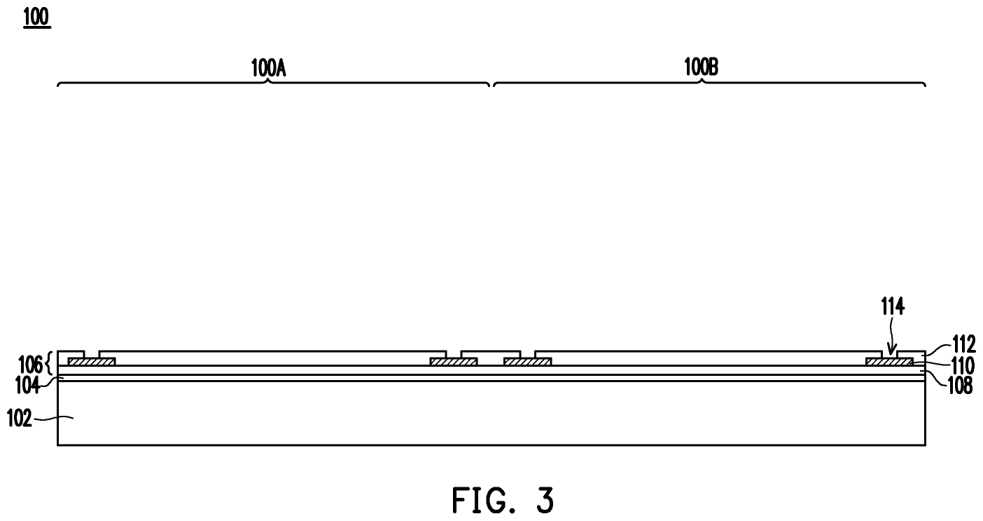

In FIG. 3, in some embodiments, a back-side redistribution structure 106 may be formed on the release layer 104. In the embodiment shown, the back-side redistribution structure 106 includes a dielectric layer 108, a metallization pattern 110 (sometimes referred to as redistribution layers or redistribution lines), and a dielectric layer 112. The back-side redistribution structure 106 is optional. In some embodiments, a dielectric layer without metallization patterns is formed on the release layer 104 in lieu of the back-side redistribution structure 106.

The dielectric layer 108 may be formed on the release layer 104. The bottom surface of the dielectric layer 108 may be in contact with the top surface of the release layer 104. In some embodiments, the dielectric layer 108 is formed of a polymer, such as polybenzoxazole (PBO), polyimide, benzocyclobutene (BCB), or the like. In other embodiments, the dielectric layer 108 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 108 may be formed by any acceptable deposition process, such as spin coating, CVD, laminating, the like, or a combination thereof.

The metallization pattern 110 may be formed on the dielectric layer 108. As an example to form metallization pattern 110, a seed layer is formed over the dielectric layer 108. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist is then formed and patterned on the seed layer. The photoresist may be formed by spin coating or the like and may be exposed to light for patterning. The pattern of the photoresist corresponds to the metallization pattern 110. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern 110.

The dielectric layer 112 may be formed on the metallization pattern 110 and the dielectric layer 108. In some embodiments, the dielectric layer 112 is formed of a polymer, which may be a photo-sensitive material such as PBO, polyimide, BCB, or the like, that may be patterned using a lithography mask. In other embodiments, the dielectric layer 112 is formed of a nitride such as silicon nitride; an oxide such as silicon oxide, PSG, BSG, BPSG; or the like. The dielectric layer 112 may be formed by spin coating, lamination, CVD, the like, or a combination thereof. The dielectric layer 112 is then patterned to form openings 114 exposing portions of the metallization pattern 110. The patterning may be formed by an acceptable process, such as by exposing the dielectric layer 112 to light when the dielectric layer 112 is a photo-sensitive material or by etching using, for example, an anisotropic etch. If the dielectric layer 112 is a photo-sensitive material, the dielectric layer 124 can be developed after the exposure.

It should be appreciated that the back-side redistribution structure 106 may include any number of dielectric layers and metallization patterns. If more dielectric layers and metallization patterns are to be formed, steps and processes discussed above may be repeated. The metallization patterns may include conductive lines and conductive vias. The conductive vias may be formed during the formation of the metallization pattern by forming the seed layer and conductive material of the metallization pattern in the opening of the underlying dielectric layer. The conductive vias may therefore interconnect and electrically couple the various conductive lines.

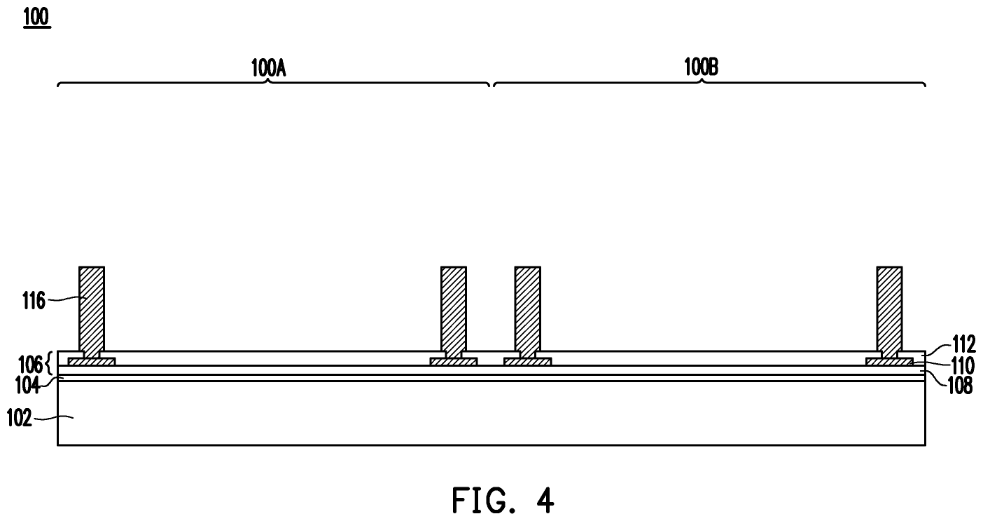

In FIG. 4, in embodiments which use the back-side redistribution structure 106, through vias 116 may be formed in the openings 114 which extend away from the topmost dielectric layer of the back-side redistribution structure 106 (e.g., the dielectric layer 112). As an example to form the through vias 116, a seed layer (not shown) is formed over the back-side redistribution structure 106, e.g., on the dielectric layer 112 and portions of the metallization pattern 110 exposed by the openings 114. In some embodiments, the seed layer is a metal layer, which may be a single layer or a composite layer comprising a plurality of sub-layers formed of different materials. In a particular embodiment, the seed layer comprises a titanium layer and a copper layer over the titanium layer. The seed layer may be formed using, for example, PVD or the like. A photoresist is formed and patterned on the seed layer. The photoresist may be formed by spin coating or the like and may be exposed to light for patterning. The pattern of the photoresist corresponds to conductive vias. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the through vias 116.

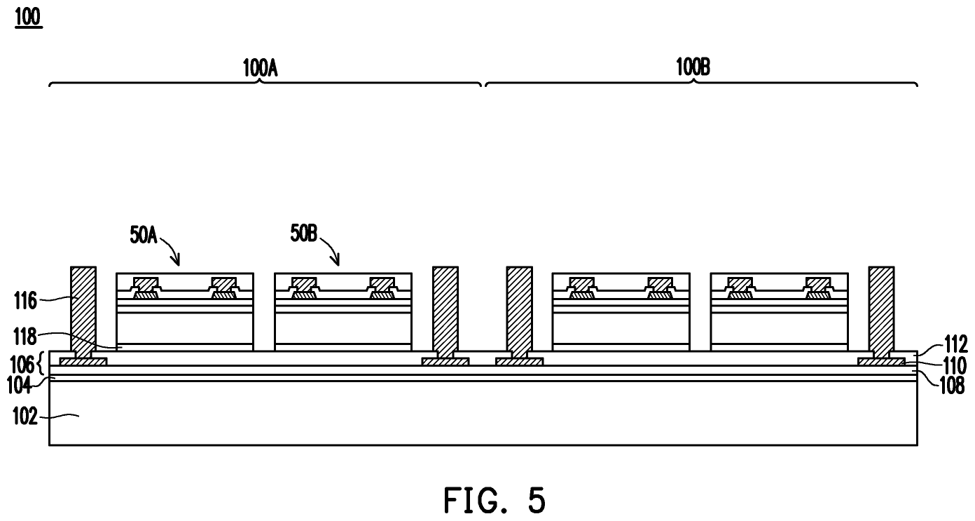

In FIG. 5, integrated circuit dies 50 are adhered to the dielectric layer 112 by an adhesive 118. A desired type and quantity of integrated circuit dies 50 are adhered in each of the package regions 100A and 100B. In the embodiment shown, multiple integrated circuit dies 50 are adhered adjacent one another, including a first integrated circuit die 50A and a second integrated circuit die 50B, though additional integrated circuit dies 50 may be included as desired. The first integrated circuit die 50A may be a logic device, such as a central processing unit (CPU), graphics processing unit (GPU), system-on-a-chip (SoC), microcontroller, or the like. The second integrated circuit die 50B may be a memory device, such as a dynamic random access memory (DRAM) die, static random access memory (SRAM) die, hybrid memory cube (HMC) module, a high bandwidth memory (HBM) module, or the like. In some embodiments, the integrated circuit dies 50A and 50B may be the same type of dies, such as SoC dies. The first integrated circuit die 50A and second integrated circuit die 50B may be formed in processes of a same technology node, or may be formed in processes of different technology nodes. For example, the first integrated circuit die 50A may be of a more advanced process node than the second integrated circuit die 50B. The integrated circuit dies 50A and 50B may have different sizes (e.g., different heights and/or surface areas), or may have the same size (e.g., same heights and/or surface areas). The space available for the through vias 116 in the package regions 100A and 100B may be limited, particularly when the integrated circuit dies 50A and 50B include devices with a large footprint, such as SoCs. Use of the back-side redistribution structure 106 allows for an improved interconnect arrangement when the package regions 100A and 100B have limited space available for the through vias 116.

The adhesive 118 is on back-sides of the integrated circuit dies 50A and 50B which adheres the integrated circuit dies 50A and 50B to the back-side redistribution structure 106, such as to the dielectric layer 112. The adhesive 118 may be any suitable adhesive, epoxy, die attach film (DAF), or the like. The adhesive 118 may be applied to back-sides of the integrated circuit dies 50A and 50B or may be applied over the surface of the carrier substrate 102. For example, the adhesive 118 may be applied to the back-sides of the integrated circuit dies 50A and 50B before singulating to separate the integrated circuit dies 50A and 50B.

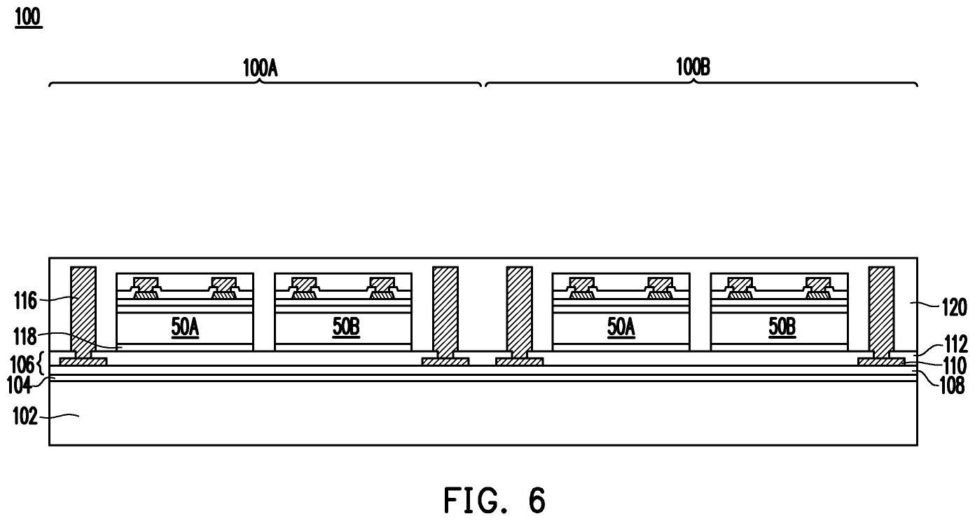

In FIG. 6, an encapsulant 120 is formed on and around the various components. After formation, the encapsulant 120 encapsulates the through vias 116 and integrated circuit dies 50A and 50B. The encapsulant 120 may be a molding compound, epoxy, or the like. The encapsulant 120 may be applied by compression molding, transfer molding, or the like, and may be formed over the carrier substrate 102 such that the through vias 116 and/or the integrated circuit dies 50A and 50B are buried or covered. The encapsulant 120 is further formed in gap regions between the integrated circuit dies 50. The encapsulant 120 may be applied in liquid or semi-liquid form and then subsequently cured.

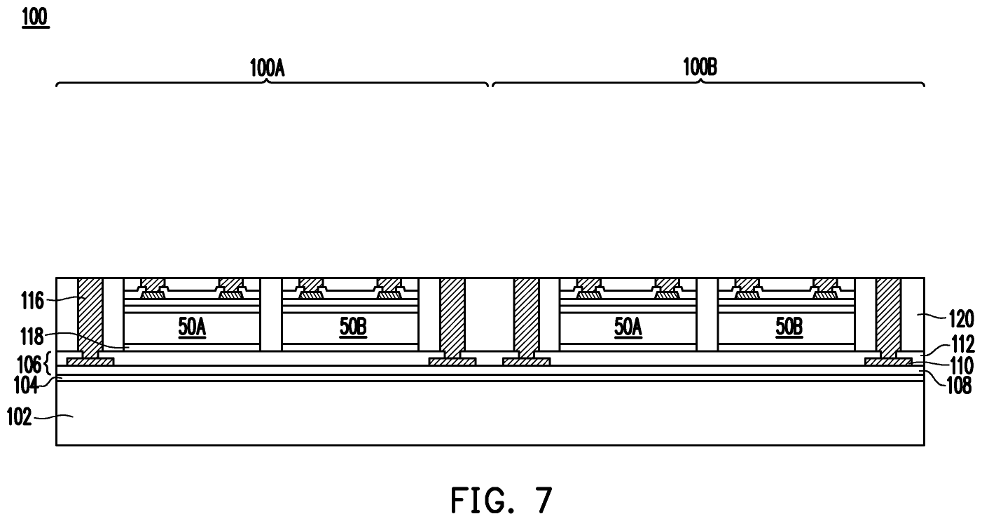

In FIG. 7, a planarization process is performed on the encapsulant 120 to expose the through vias 116 and the die connectors 66. The planarization process may also remove material of the through vias 116, dielectric layer 68, and/or die connectors 66 until the die connectors 66 and through vias 116 are exposed. Top surfaces of the through vias 116, die connectors 66, dielectric layer 68, and encapsulant 120 are coplanar after the planarization process. The planarization process may be, for example, a chemical-mechanical polish (CMP), a grinding process, or the like. In some embodiments, the planarization may be omitted, for example, if the through vias 116 and/or die connectors 66 are already exposed.

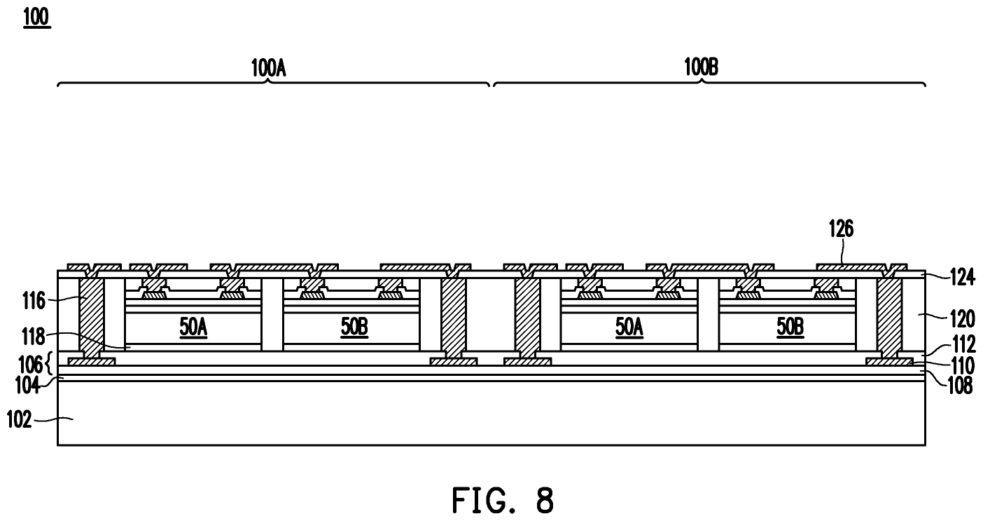

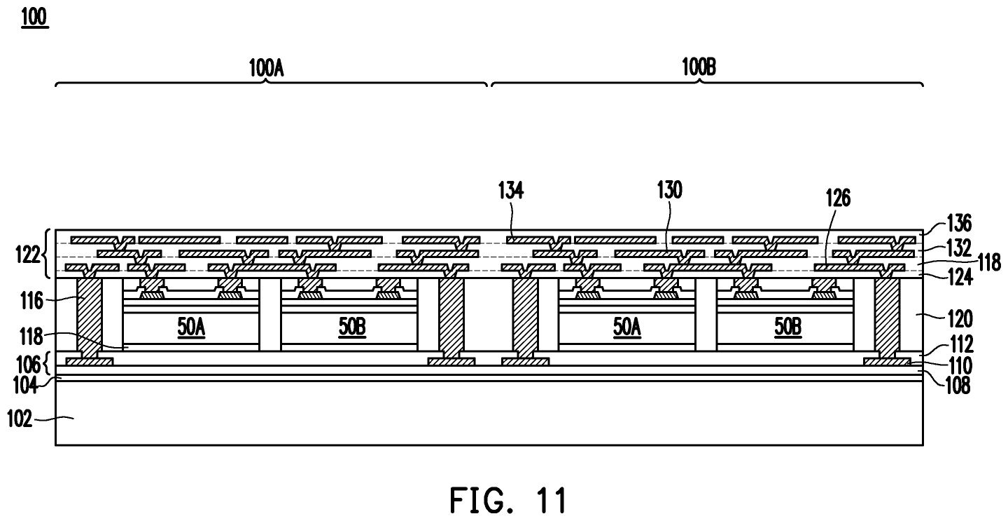

In FIGS. 8 through 11, a front-side redistribution structure 122 (see FIG. 11) is formed over the encapsulant 120, through vias 116, and integrated circuit dies 50A and 50B. The front-side redistribution structure 122 includes dielectric layers 124, 128, 132, and 136; and metallization patterns 126, 130, and 134. The metallization patterns may also be referred to as redistribution layers or redistribution lines. The front-side redistribution structure 122 is shown as an example having three layers of metallization patterns. More or fewer dielectric layers and metallization patterns may be formed in the front-side redistribution structure 122. If fewer dielectric layers and metallization patterns are to be formed, steps and process discussed below may be omitted. If more dielectric layers and metallization patterns are to be formed, steps and processes discussed below may be repeated.

In FIG. 8, the dielectric layer 124 is deposited on the encapsulant 120, through vias 116, and die connectors 66. In some embodiments, the dielectric layer 124 is formed of a photo-sensitive material such as PBO, polyimide, BCB, or the like, which may be patterned using a lithography mask. The dielectric layer 124 may be formed by spin coating, lamination, CVD, the like, or a combination thereof. The dielectric layer 124 is then patterned. The patterning forms openings exposing portions of the through vias 116 and the die connectors 66. The patterning may be by an acceptable process, such as by exposing the dielectric layer 124 to light when the dielectric layer 124 is a photo-sensitive material or by etching using, for example, an anisotropic etch. If the dielectric layer 124 is a photo-sensitive material, the dielectric layer 124 can be developed after the exposure.

The metallization pattern 126 is then formed. The metallization pattern 126 includes line portions (also referred to as conductive lines) on and extending along the major surface of the dielectric layer 124. The metallization pattern 126 further includes via portions (also referred to as conductive vias) extending through the dielectric layer 124 to physically and electrically couple the through vias 116 and the integrated circuit dies 50. As an example to form the metallization pattern 126, a seed layer is formed over the dielectric layer 124 and in the openings extending through the dielectric layer 124. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 126. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 126. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

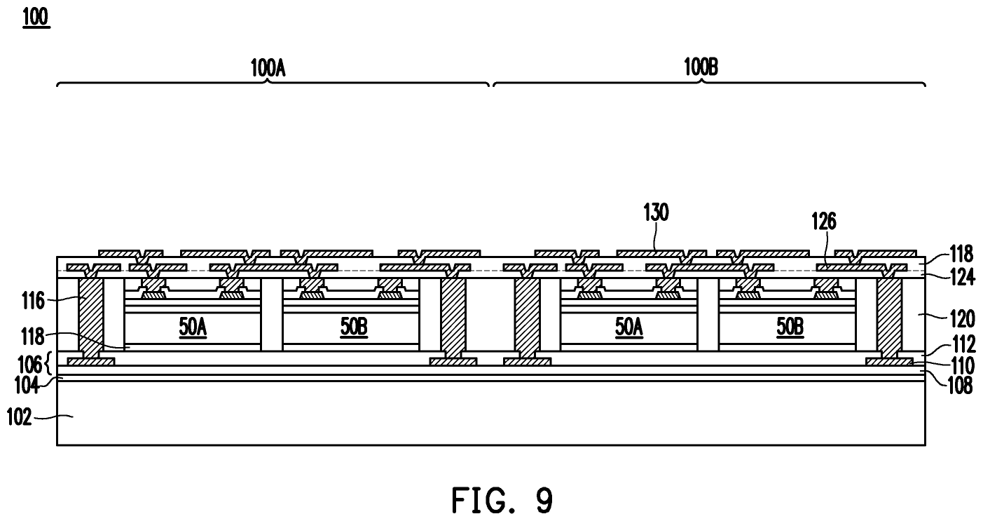

In FIG. 9, the dielectric layer 128 is deposited on the metallization pattern 126 and dielectric layer 124. The dielectric layer 128 may be formed in a manner similar to the dielectric layer 124, and may be formed of a similar material as the dielectric layer 124.

The metallization pattern 130 is then formed. The metallization pattern 130 includes line portions on and extending along the major surface of the dielectric layer 128. The metallization pattern 130 further includes via portions extending through the dielectric layer 128 to physically and electrically couple the metallization pattern 126. The metallization pattern 130 may be formed in a similar manner and of a similar material as the metallization pattern 126. In some embodiments, the metallization pattern 130 has a different size than the metallization pattern 126. For example, the conductive lines and/or vias of the metallization pattern 130 may be wider or thicker than the conductive lines and/or vias of the metallization pattern 126. Further, the metallization pattern 130 may be formed to a greater pitch than the metallization pattern 126.

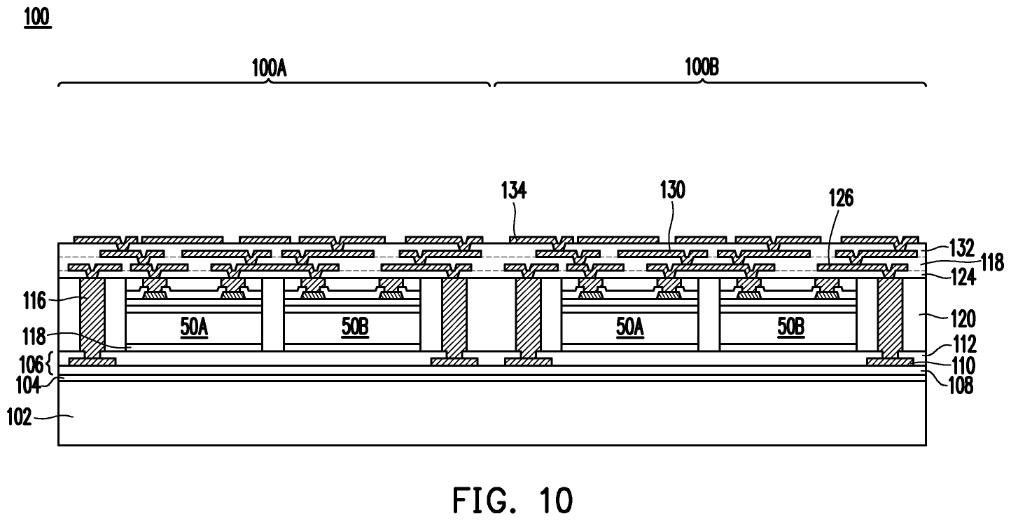

In FIG. 10, the dielectric layer 132 is deposited on the metallization pattern 130 and dielectric layer 128. The dielectric layer 132 may be formed in a manner similar to the dielectric layer 124, and may be formed of a similar material as the dielectric layer 124.

The metallization pattern 134 is then formed. The metallization pattern 134 includes line portions on and extending along the major surface of the dielectric layer 132. The metallization pattern 134 further includes via portions extending through the dielectric layer 132 to physically and electrically couple the metallization pattern 130. The metallization pattern 134 may be formed in a similar manner and of a similar material as the metallization pattern 126. The metallization pattern 134 is the topmost metallization pattern of the front-side redistribution structure 122. As such, all of the intermediate metallization patterns of the front-side redistribution structure 122 (e.g., the metallization patterns 126 and 130) are disposed between the metallization pattern 134 and the integrated circuit dies 50A and 50B. In some embodiments, the metallization pattern 134 has a different size than the metallization patterns 126 and 130. For example, the conductive lines and/or vias of the metallization pattern 134 may be wider or thicker than the conductive lines and/or vias of the metallization patterns 126 and 130. Further, the metallization pattern 134 may be formed to a greater pitch than the metallization pattern 130.

In FIG. 11, the dielectric layer 136 is deposited on the metallization pattern 134 and dielectric layer 132. The dielectric layer 136 may be formed in a manner similar to the dielectric layer 124, and may be formed of the same material as the dielectric layer 124. The dielectric layer 136 is the topmost dielectric layer of the front-side redistribution structure 122. As such, all of the metallization patterns of the front-side redistribution structure 122 (e.g., the metallization patterns 126, 130, and 134) are disposed between the dielectric layer 136 and the integrated circuit dies 50A and 50B. Further, all of the intermediate dielectric layers of the front-side redistribution structure 122 (e.g., the dielectric layers 124, 128, 132) are disposed between the dielectric layer 136 and the integrated circuit dies 50A and 50B.

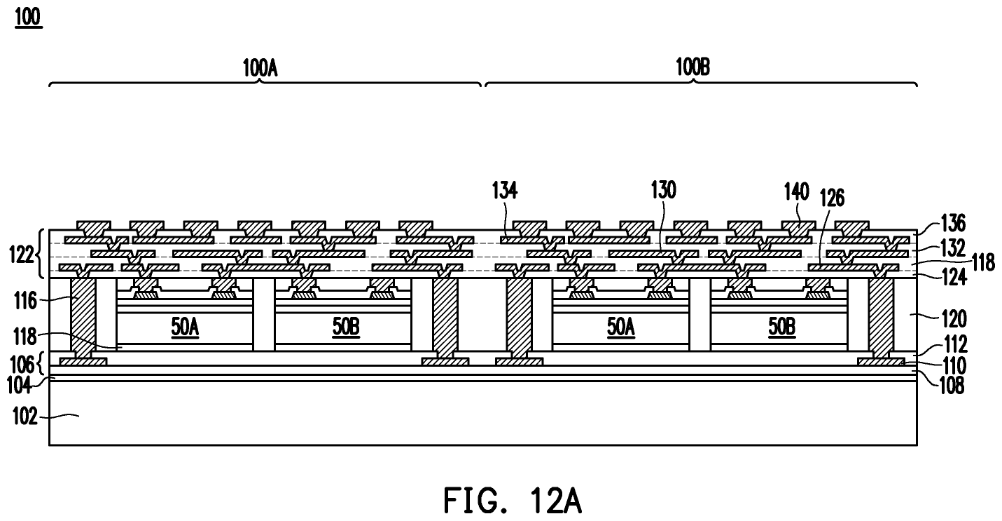

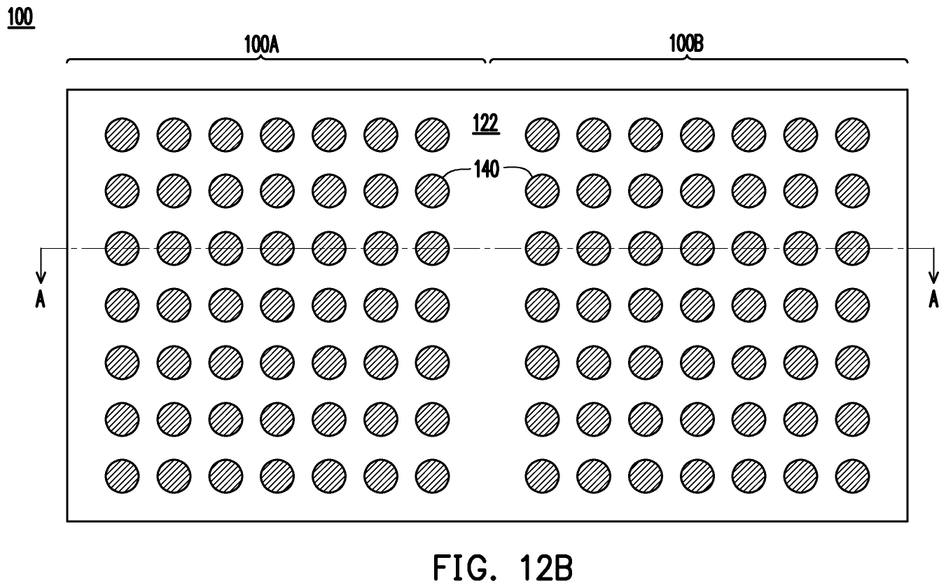

In FIGS. 12A and 12B, contact pads 140 are formed for external connection to the front-side redistribution structure 122. The contact pads 140 have bump portions on and extending along the major surface of the dielectric layer 136, and have via portions extending through the dielectric layer 136 to physically and electrically couple the metallization pattern 134. As a result, the contact pads 140 are electrically coupled to the through vias 116 and the integrated circuit dies 50A and 50B. In some embodiments, the contact pads 140 may have an upper surface which is level with the upper surface of the dielectric layer 136. The contact pads 140 may be formed of the same material as the metallization pattern 126. In some embodiments, the contact pads 140 have a different size than the metallization patterns 126, 130, and 134.

Contact pads 140 are formed for providing connector points for an IVR chip (or other device) which may be bonded in a subsequent process. The contact pads 140 may have bump portions on and extending along the major surface of the dielectric layer 136 and via portions extending through the dielectric layer 136 to physically and electrically couple the metallization pattern 134. As a result, the contact pads 140 are electrically coupled to the through vias 116 and the integrated circuit dies 50A and 50B. In some embodiments, the contact pads 140 may have an upper surface which is level with the upper surface of the dielectric layer 136. The contact pads 140 may be formed of the same material as the metallization pattern 126. In some embodiments, the contact pads 140 have a different size than the metallization patterns 126, 130, and 134. The metallization pattern 134 may electrically couple certain of the contact pads 140 to voltage inputs of the integrated circuit dies 50A and/or 50B for routing a regulated voltage output from an IVR chip (discussed in detail further below) to the integrated circuit dies 50A and/or 50B. The metallization pattern 134 may electrically couple others of the contact pads 140 to certain of the contact pads 138 for routing a voltage input signal to the IVR chip.

Other features and processes may also be included. For example, testing structures may be included to aid in the verification testing of the three dimensional (3D) packaging or 3D Integrated Circuit (3DIC) devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

FIG. 12B is a top-down view of the structure of FIG. 12A, and the view of FIG. 12A is a cross-sectional view along the A-A line of FIG. 12B. As illustrated in FIG. 12B, the contact pads 140 may be distributed in a pattern along the upper surface of the redistribution structure 122.

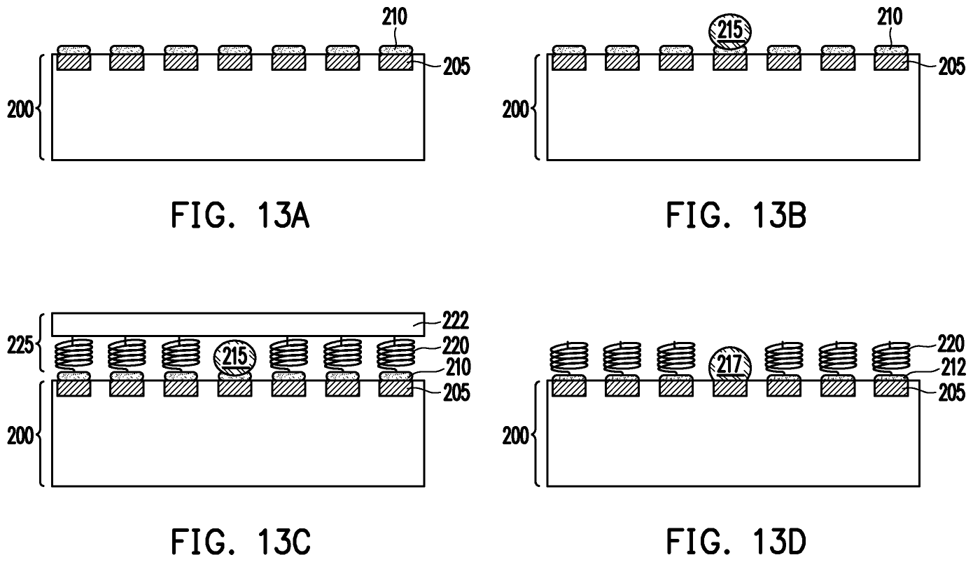

FIGS. 13A through 13D illustrate a process of preparing a second package component 200 for mounting to the contact pads 140 of the package regions 100A and 100B. Springs 220, such as microsprings, are attached to select contact pads 205 of the second package components 200. The springs 220 may be provided on a spring carrier 225 (as described below). The springs 220 may be made of a coiled conductive material with a high melting point, such as copper, nickel, gold, aluminum, or alloys thereof. In some embodiments, the number of turns (i.e., the number of coils) may be between about 10 to 30, though other values may be used. Further, the springs 220 may have better electro-migration resistance than solder connectors and so may be utilized in connections where better electro-migration resistance is more critical. In some embodiments, the springs 220 may have a nominal height between about 400 μm and about 3000 μm.

In FIG. 13A, the second package component 200 is provided which has contact pads 205 disposed at an upper surface thereof. The second package component 200 may be any suitable package component, including any of the integrated circuit devices discussed above with respect to integrated circuit dies 50A and 50B. In an embodiment, the second package component 200 includes an integrated voltage regulator (IVR). A solder paste region 210 may be formed on the contact p-ads 205 by applying a solder paste to the contact pads 205 using any appropriate process, such as by a printing technique. The solder paste 210 may, for example, be any suitable solder material such as SAC305 solder and may include flux. Other solder materials may be used.

In FIG. 13B, in some embodiments, solder balls 215 may be selectively positioned over one or more of the solder paste regions 210. The solder balls 215 may be placed using any suitable process, such as a solder ball drop process or pick and place process to position the solder balls 215 over the selected solder past regions 210.

In FIG. 13C, a spring carrier 225 is provided and positioned over the second package components 200, aligning each of the springs 220 with the remaining solder paste regions 210. The spring carrier 225 may be positioned using a pick and place process. The spring carrier 225 may, for example, be a flip pack including a number of springs 220 attached to a handler 222. In embodiments which do not include the solder balls 215, each of the solder paste regions 210 may have a spring 220 aligned to it. In some embodiments, one or more of the solder paste regions 210 may remain unused by either a spring 220 or solder ball 215.

In FIG. 13D, a reflow process is performed to melt the solder paste regions 210, thereby forming solder regions 212 and embedding one end of the springs 220 into the solder regions 212. For sites having a solder ball 215, the reflow process causes the solder ball 215 and solder paste regions 210 to melt together and form solder regions 217. The handler 222 is removed and a flux cleaning process is used to clean flux residue from the solder regions 212 and solder regions 217 (if any). The flux cleaning process may be performed before or after removing the handler 222.

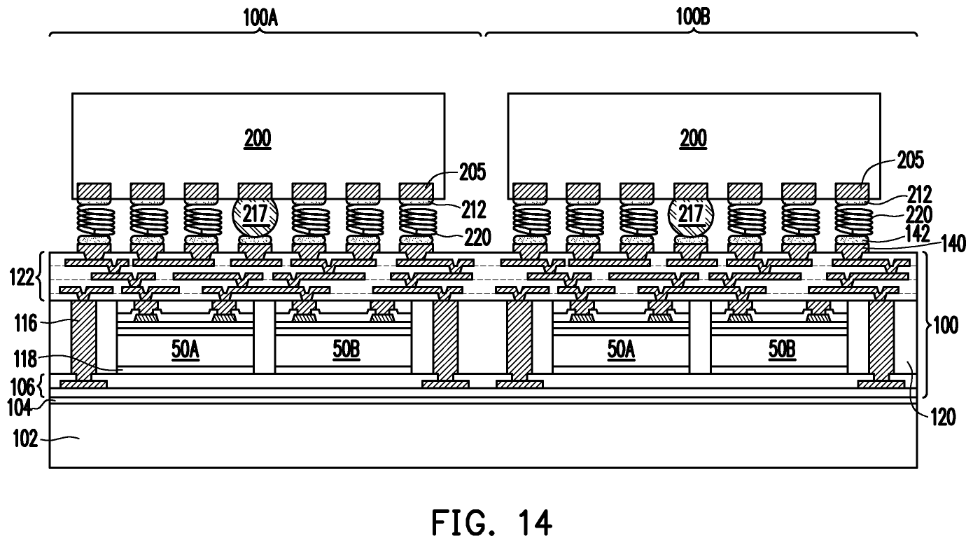

In FIG. 14, the second package components 200 are attached to the first package components 100 at the package regions 100A and 100B. Solder paste regions 142 may be formed over the contact pads 140 using processes and materials similar to those used to form the solder paste regions 210, described above. After forming the solder paste regions 142, the second package components 200 may be positioned over each of the package regions 100A and 100B using a pick and place process to align each of the springs 220 and optional solder regions 217 over respective contact pads 140. The free end of the springs 220 are made to contact respective solder paste regions 142 and an exposed surface of the solder regions 217 (if used) are made to contact respective solder paste regions 142. Pressure may be used to press down on the second package components 200 to ensure that each of the springs 220 and solder regions 217 are contacting a solder paste region 142. Pressing the second package components 200 may slightly deform the springs of the springs 220 to account for height variations between the springs 220 and the solder regions 217.

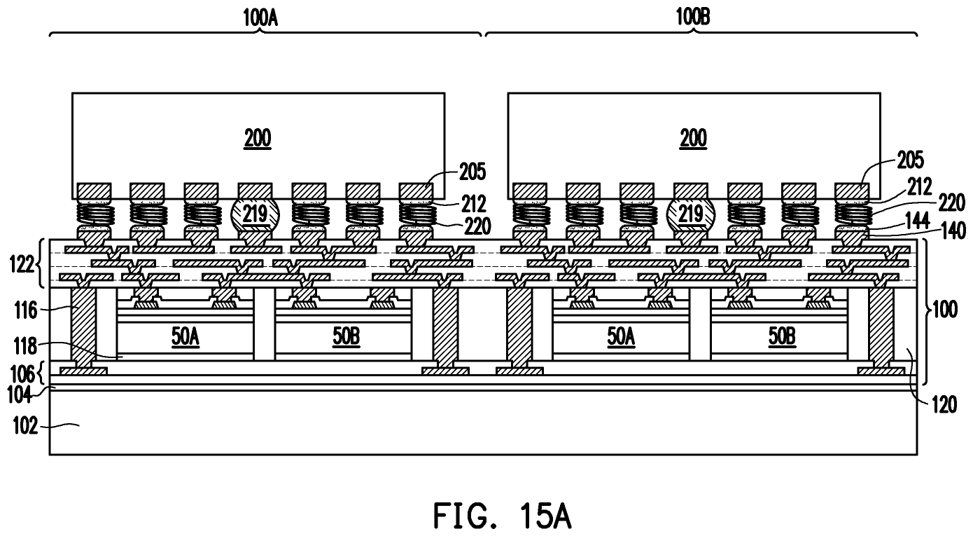

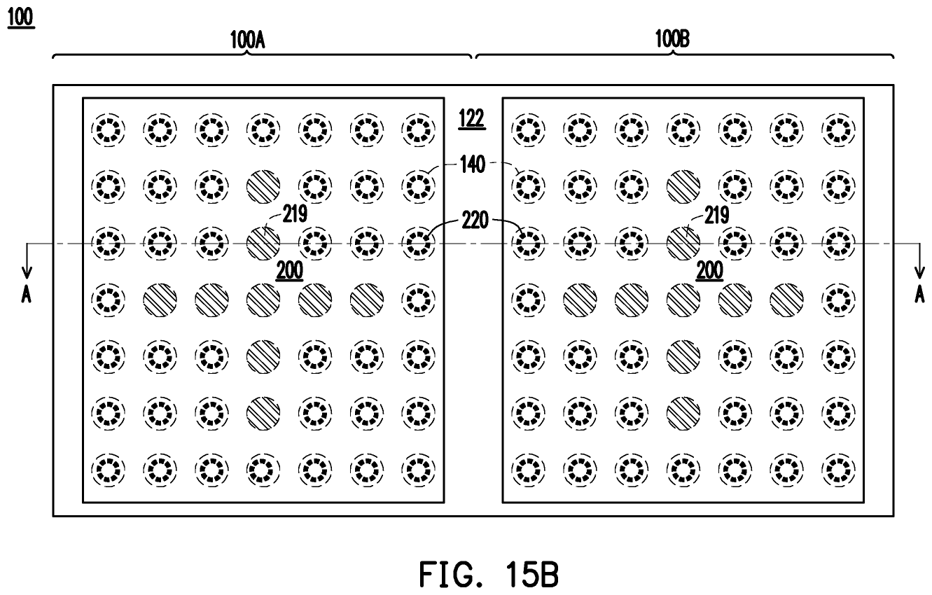

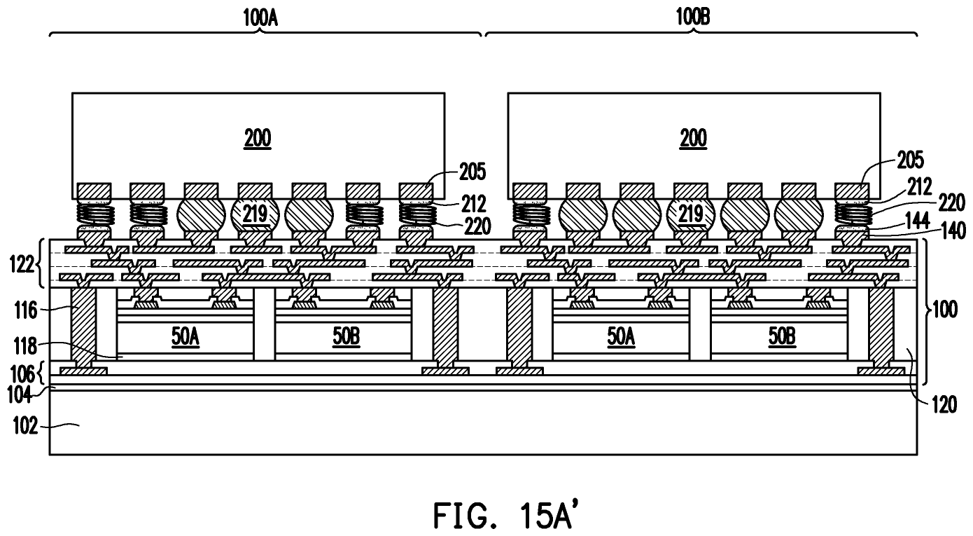

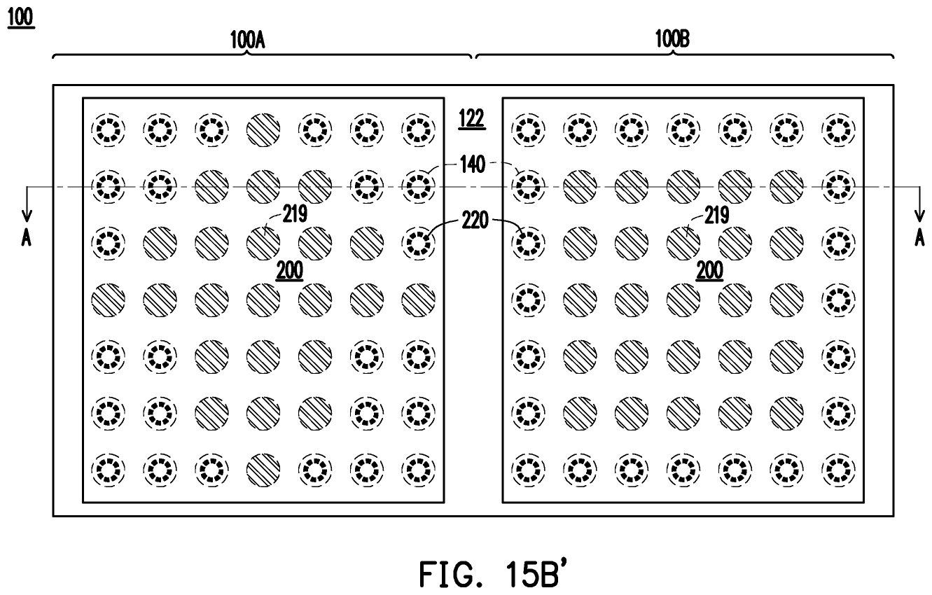

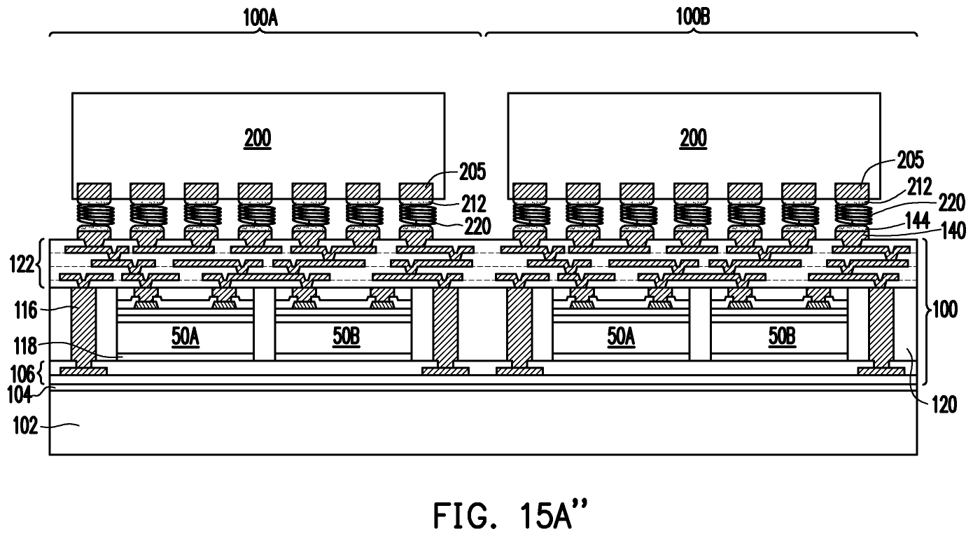

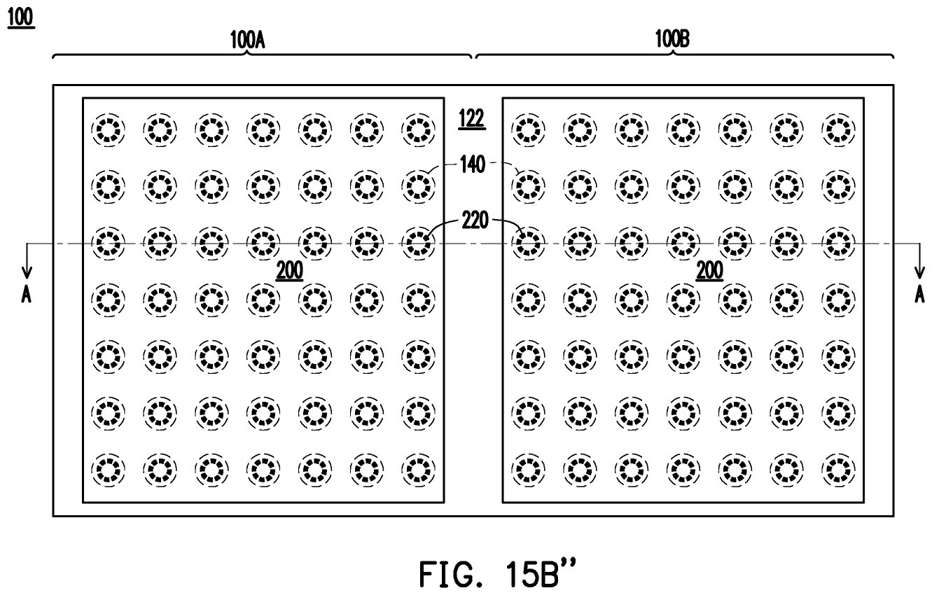

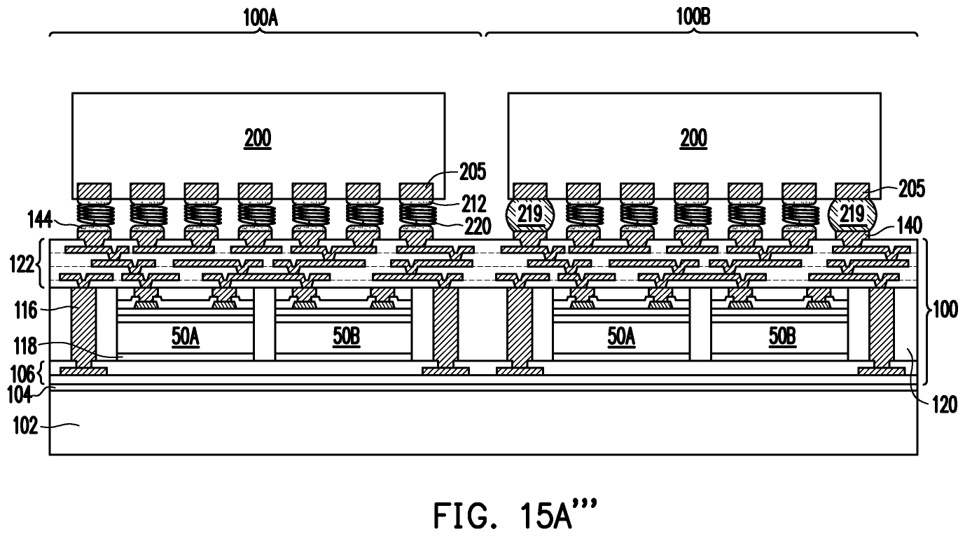

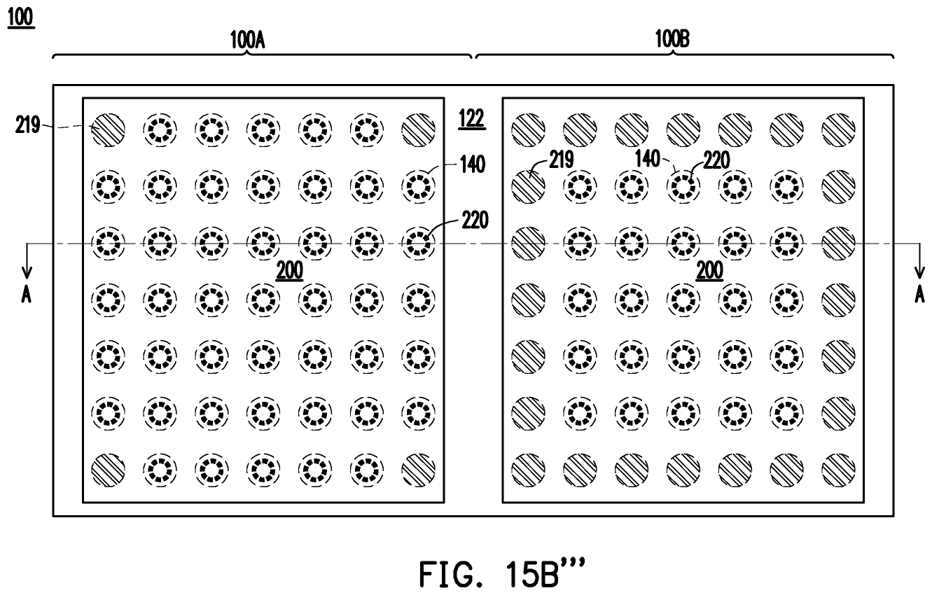

In FIGS. 15A and 15B, a reflow process is used to reflow the solder paste regions 142 to form the solder regions 144 which attach the springs 220 both physically and electrically to the solder regions 144 and hence their corresponding contact pads 140. For sites having a solder region 217, the reflow process will cause the solder region 217 to melt and combine with the solder paste region 142 to form the solder region 219, thereby physically and electrically coupling the contact pads 205 with the corresponding contact pads 140. The reflow may be performed at a low enough temperature so that the solder paste regions 142 melt, but the solder regions 212 do not. After the reflow process a flux cleaning process may be used to clean flux from the solder regions 144 and solder regions 219 (if used).

FIG. 15B is a top-down view of the structure of FIG. 15A, and the view of FIG. 15A is a cross-sectional view along the A-A line of FIG. 15B. Some features have been omitted for clarity. Springs 220 are shown in dashed lines and solder regions 219 are outlined in dashed lines. As illustrated in FIG. 15B, springs 220 may be utilized along the edges and in the corners of the second package components 200 and solder regions 219 may be utilized in the center connectors between the second package components 200 and the corresponding contact pads 140. As discussed in further detail below, other arrangements are possible and may be used.

Because the springs 220 are formed of a material with a higher melting point than that of the solder, using the springs 220 maintains a minimum distance between the second package component 200 and the first package component 100. As such, surface mount devices (not shown) may be attached to the contact pads 140 prior to attaching the second package component 200, and the springs 220 may maintain a distance between the second package component 200 and the first package component 100 so that the surface mount devices do not suffer from solder bridging that can occur due to squeeze out when attaching devices by solder connectors (e.g., ball grid array connectors) alone. In some embodiments the minimum distance may be between about 100 μm and about 4000 μm.

FIGS. 15A′ and 15B′, FIGS. 15A″ and 15B″, and FIGS. 15A″′ and 15B″′ each illustrate various arrangements of the springs 220 and solder regions 219 following the reflow process described with respect to FIGS. 15A and 15B. FIGS. 15A′, 15A″, 15A″′ are cross-sectional views of corresponding respective FIGS. 15B′, 15B″, 15B″′ along the reference line A-A. And FIGS. 15B′, 15B″, 15B″′ are top down views of each of the corresponding respective FIGS. 15A′, 15A″, 15A″′. Some features have been omitted for clarity. It should be appreciated that the illustrated arrangements are non-limiting and other arrangements may be used. For the sake of brevity, the illustrations may show a different arrangement used in package region 100A than used in package region 100B, however, it should be understood that any of these arrangements may be used in both of the package regions 100A and 100B at the same time. In some embodiments, the arrangement of springs 220 and solder regions 219 may be same for each of the package regions 100A and 100B (and others not specifically illustrated), while in other embodiments one or more of the arrangements of springs 220 and solder regions 219 may be unique in one or more of the package regions. For each of the discussed arrangements, the opposite arrangement may also be understood as being specifically illustrated by reversing the placement of the springs 220 and solder regions 219, such as illustrated between the package region 100B of FIG. 15B′ and the package region 100B of FIG. 15B″′.

In FIGS. 15A′ and 15B′, the springs 220 may be utilized in the corner regions, such as illustrated in the package region 100A of FIG. 15B′, resulting in a triangular arrangement of the springs 220. The solder regions 219 may form a diamond shaped arrangement in top-down view. The springs 220 may be utilized along the peripheral connections, such as illustrated in the package region 100B of FIG. 15B′, and the solder regions 219 may form a rectangular arrangement in top-down view.

In FIGS. 15A″ and 15B″, the springs 220 may be utilized in each of the contact positions and the solder regions 219 may be omitted.

In FIGS. 15A″′ and 15B″′, the springs 220 may be utilized in each of the contact positions except the corner contact pads, such as illustrated in the package region 100A of FIG. 15B″′. The solder regions 219 may be used in each of the corner contacts. The springs 220 may be utilized for each of the interior connections, such as illustrated in the package region 100B of FIG. 15B″′, forming a rectangular arrangement in top-down view, and the solder regions 219 may be used along the peripheral connections.

Following the attachment of the second package components 200 to the package regions 100A and 100B, the joints of the springs 220 and the contact pads 140 and contact pads 205 may be checked for physical connection. X-ray images may be taken of the structure of FIGS. 15A and 15B and the joints checked between the springs 220 and the solder regions 144 and the joints checked between the springs 220 and the solder regions 212. Views of various angles of the structure may be taken by a suitable x-ray device. Because the springs 220 are not solid structures (being a coiled wire surrounded by air), they will allow the x-rays to pass through the air and only be substantially absorbed by the metallic components, resulting in images with observable joints. Imaging by x-ray is more cost efficient than other imaging techniques, such as by electron microscope and so checking the coupling between the second package components 200 and the package regions 100A and 100B may be performed using more cost-efficient procedures, resulting in increased yield for decreased cost. If a joint is observed to not be connected. Pressure to the second package components 200 may be increased and the solder regions 144 and 212 reflowed again to attempt connection again. Following the second reflow, x-ray images may be taken again to verify the joint coupling.

In FIG. 16, in some embodiments, an underfill 250 is formed between the second package components 200 and the package regions 100A and 100B. The underfill 250 may protect the joints resulting from the reflowing of the solder regions 144 and 212. The underfill may be formed by a capillary flow process after the second package components 200 are attached, or may be formed by a suitable deposition method before the second package components 200 are attached.

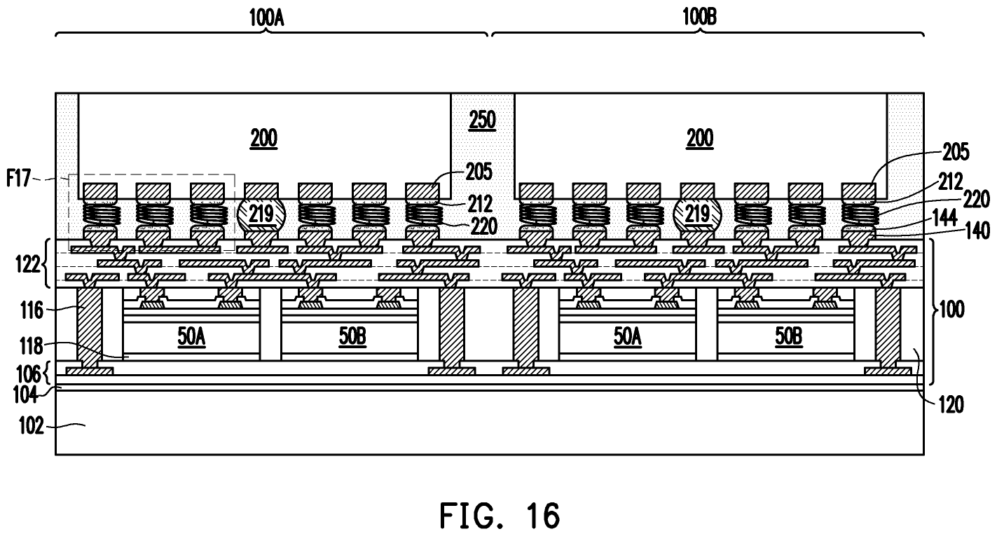

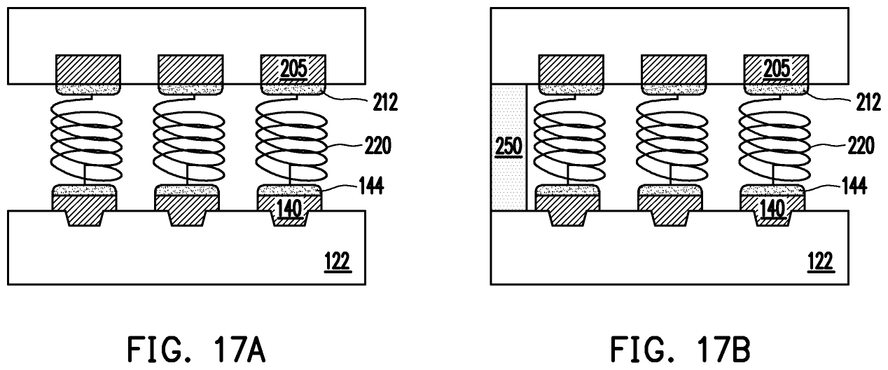

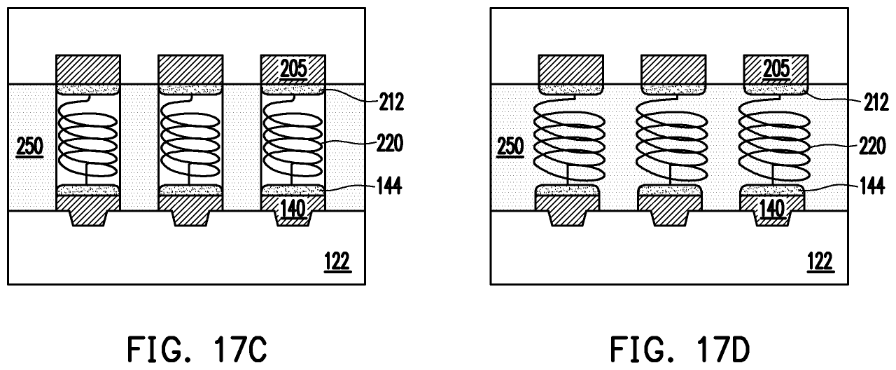

FIGS. 17A, 17B, 17C, and 17D illustrate various options for the underfill 250. Each of these illustrates a magnified view of the dashed box F17 of FIG. 16. Some features have been omitted for clarity. In FIG. 17A, an underfill 250 is not used. In FIG. 17B, the underfill 250 is used and applied such that it surrounds the springs 220 without going between any two of the springs 220. As such in FIG. 17B, the underfill 250 extends from the second package component 200 to the redistribution structure 122 only at the edge of the second package component 200. In FIG. 17C, the underfill 250 may extend from the second package component 200 to the redistribution structure 122 between the springs 220 to encapsulate the springs 220, but does not extend into the spring coil or at least does not extend fully into the spring coil so that air remains in the center of the spring coil. The underfill 250 may extend vertically between loops of the spring coil or may just touch the outsides of the loops. The underfill 250 may contact each of the contact pads 140, the solder regions 144, the solder regions 212, and/or the contact pads 205. In FIG. 17D, the underfill 250 may extend fully into the coils of the springs 220 to fully encapsulate and fully fix their movement relative to the underfill 250. The underfill 250 may contact and encapsulate each of the contact pads 140, the solder regions 144, the solder regions 212, and/or the contact pads 205.

Utilizing the springs 220 provides the ability for the second package components 200 to move relative to the first package components 100 without stressing the joints beyond capability and causing them to break. Typical connectors are rigid, however, the springs 220 allow movement. Movement may occur, for example, during heating and cooling cycles in forming the device as well as in operation of the final device itself. In some cases, warpage of the various components may cause vertical stresses as some portions of the warped component may tend to push away from the other component. In some cases, expansion and contraction of the various components at different rates may cause horizontal stresses. The springs 220 can accommodate both vertical and horizontal stresses better than rigid connectors due to their flexibility.

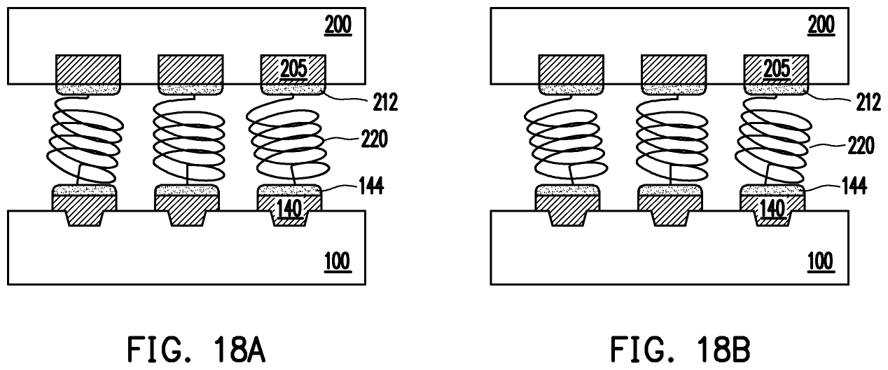

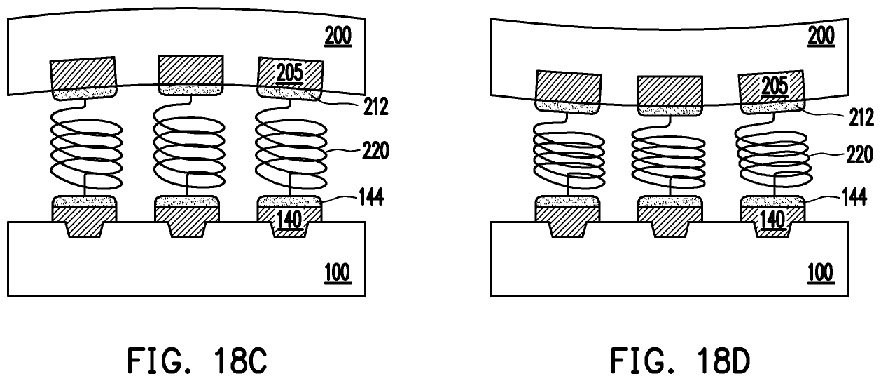

FIGS. 18A, 18B, 18C, and 18D illustrate various modes of deformation which the springs 220 can be subjected. These views are similar to those illustrated in FIG. 17A, however, it should be appreciated that any of the arrangements of underfill 250 may be utilized with these views. FIG. 18A illustrates a situation where the first package component 100 has expanded at a greater rate than the second package component 200, causing some of the springs 220 to tilt inward. However, because the springs 220 are deformable and flexible, the differences in expansion may be accommodated by the springs 220 and the joints may remain intact. FIG. 18B illustrates a situation where the second package component 200 expands at a greater rate than the first package component 100, causing some of the springs 220 to tilt outward. However, because the springs 220 are deformable and flexible, the differences in expansion may be accommodated by the springs 220 and the joints may remain intact. Where the second package component 200, for example, is an integrated voltage regulator the coefficient of thermal expansion (CTE) may be about 19 10⁻⁶/K while the first package component 100 may have a CTE of about 8 10⁻⁶/K.

FIG. 18C illustrates a situation where the second package component 200 warps so that a portion of the second package component 200 is pulled away from the first package component 100. However, because the springs 220 are deformable and flexible, the vertical differences resulting from the warpage may be accommodated by the springs 220 and the joints may remain intact. FIG. 18D illustrates a situation where the second package component 200 warps so that a portion of the second package component 200 pushes toward the first package component 100. However, because the springs 220 are deformable and flexible, the vertical differences resulting from the warpage may be accommodated by the springs 220 and the joints may remain intact. Further, because the springs 220 are deformable, they may deform without causing solder squeeze and bridging that can occur with rigid connectors. These features can be combined so that springs 220 may accommodate both lateral and vertical differences.

If utilizing an underfill, such as the underfill 250 described above with respect to FIGS. 17B, 17C, and 17D, the underfill 250 may be applied to fix one or more parts of the second package component 200 to the first package component 100. Such fixation may occur, for example, after such movement has occurred between the second package component 200 and the first package component 100 such that after the underfill 250 has cured, their positions are deformed from their original placement, but with little joint stress on the joints between the ends of the springs 220 and the solder regions 144 and 212.

As an illustration of the robustness of the joint strength due to the flexibility of the springs 220, a device was attached to a ceramic substrate by a ball grid array (rigid connectors). The combined structure was cycled between −55° C. and 125° C. and one or more connectors were found to fail after about 300 cycles. The same type of device was attached to the same type of ceramic substrate by springs, such as the springs 220. The same conditions applied to this structure resulted in connector failure after 5000 cycles, a projected life cycle improvement of more than 16 times. The same type of device was attached to a plastic substrate by a ball grid array (rigid connectors). The combined structure was cycled between −55° C. and 125° C. and one or more connectors were found to fail after about 2000 cycles. The same type of device was attached to the same type of plastic substrate by springs, such as the springs 220. The same conditions applied to this structure resulted in connector failure after 20000 cycles, a projected life cycle improvement of about 10 times. The use of springs may improve connector life cycle by between 5 and 20 times versus all rigid connectors.

The spring connectors also withstand shock conditions better than rigid connectors for more robust connector strength for use in harsh conditions. A device was attached to a substrate by a ball grid array and subjected to extreme shock repetition of 30,000 g, 40,000 g, and 50,000 g and the ball grid array failed after 7 shock cycles, 5 shock cycles, and 4 shock cycles, respectively. A same type of device attached to a same type of substrate by springs, such as the springs 220, and subjected to extreme shock repetition of 30,000 g, 40,000 g, and 50,000 g failed after 30 shock cycles, 16 shock cycles, and 8 shock cycles, resulting in a shock improvement of between about 100% and 400% or more.

As compared to a solder ball of a ball grid array, for example, the springs 220 provide excellent deformation properties. For example, whereas the modulus for a solder ball is about 49 Gpa, the modulus for a spring 220 is about 0.6 Mpa, about 81,000 to 82,000 times less modulus. As another example, whereas the elastic deformation limitation of a solder ball is about 0.05%, the elastic deformation limitation of the spring 220 is about 120%, or between about 2000 to 2800, such as about 2400 times, more elastically deformable than the solder ball. As yet another example, whereas the elongation, or distance of deflection without fracture, of a solder ball is about 21% of the thickness of the solder ball along the line of elongation, the elongation of the spring 220 is about 400%, or between about 15 and 25 times, such as about 20 times the elongation of the solder ball.

Combining some solder regions, such as the solder region 119 with the springs 120 may provide certain benefits. For example, portions of the second package component 200 may be fixed relative to the first package component 100 while other portions of the second package component 200 are allowed to move. In some embodiments, the solder regions 119 may be used for particular signals and springs 120 used for other particular signals more sensitive to voltage drop. For example, solder regions 119 may be desirable for power or ground signals which may carry large current.

Although only one second package component 200 is depicted for each package region 100A or 100B, it should be understood that multiple second package components 200 may be used as appropriate. The lateral extents of the second package components 200 may be within the lateral extents of the redistribution structure 122 (see FIG. 12). In other words, the footprint of the second package component 200 may by completely overlapped by the footprint of the package region 100A and 100B.

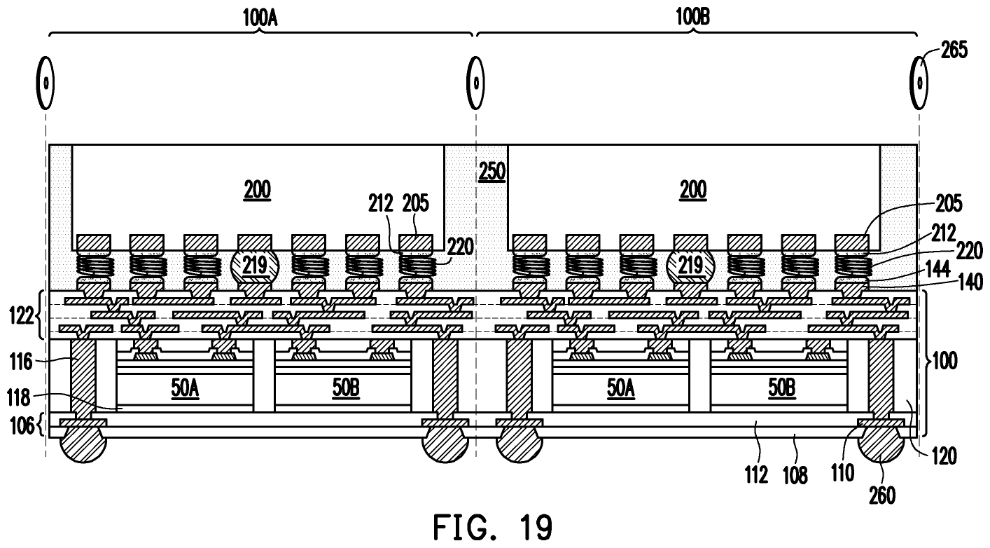

In FIG. 19, a carrier substrate de-bonding is performed to detach (or “de-bond”) the carrier substrate 102 (see FIG. 16) from the second package components first package components 100, e.g., package regions 100A and 100B. In accordance with some embodiments, the de-bonding includes projecting a light such as a laser light or an UV light on the release layer 104 so that the release layer 104 decomposes under the heat of the light and the carrier substrate 102 can be removed. The structure may then be flipped over and placed on a tape (not shown), such as a blue tape for singulation.

Also in FIG. 19, openings are formed in the dielectric layer 108 to expose the metallization pattern 110 and conductive connectors 260 are formed in the openings of the dielectric layer 108. In some embodiments, under-bump metallurgies (UBMs) may be formed prior to forming the conductive connectors 260. In other embodiments, the conductive connectors 260 may be formed on the exposed portions of the metallization pattern 110. In embodiments utilizing UBMs, the UBMs have bump portions on and extending along the major surface of the dielectric layer 108, and have via portions extending through the dielectric layer 108 to physically and electrically couple the metallization pattern 110. The UBMs may be formed of the same material as the metallization pattern 110. The conductive connectors 260 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 260 may include a conductive material such as solder, copper, aluminum, gold, nickel, silver, palladium, tin, the like, or a combination thereof. In some embodiments, the conductive connectors 260 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 260 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

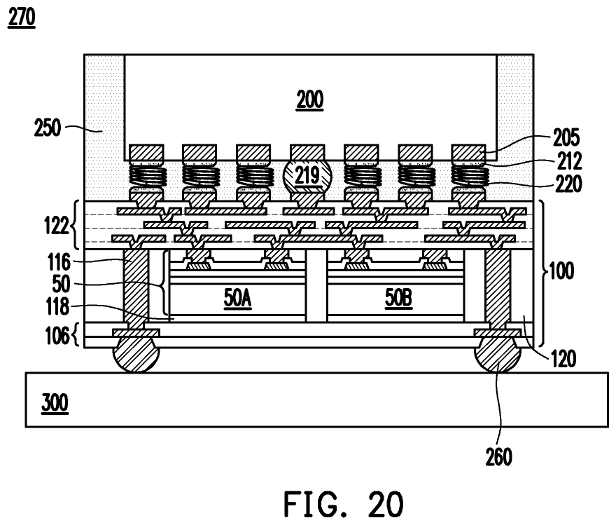

In FIG. 19, a singulation process 265 is performed by sawing along scribe line regions, e.g., between the package region 100A and the package region 100B. The sawing singulates the package region 100A from the package region 100B. The resulting, singulated package 270 (see FIG. 20) includes the package region 100A or the package region 100B. The singulation process 265 may include laser cutting, etching, sawing, or combinations thereof.

In FIG. 20, each singulated package 270 includes an embedded integrated circuit die 50 and a fan out redistribution structure 122. Although one method was described above for forming one configuration for the first package component 100, other methods and other configurations may be used. A second package component 200 is mounted to the first package component by springs 220 and optional solder regions 219, providing connector flexibility. An optional underfill 250 may be applied to stabilize the second package component 200, to fully fix or partially fix the second package component 200 to the first package component 100, for example, after some deformation is realized.

Each singulated package 270 may be further used, for example, by mounting to a printed circuit board 300 or other device using the conductive connectors 260. The printed circuit board 300 may include active and passive components as well as other devices. In some embodiments the printed circuit board 300 may be an interposer or another package component. The printed circuit board 300 may include a voltage source device mounted thereto which provides a high voltage signal to conductive connectors 260, which is then routed through the substrate 300 to various components.

By attaching a second package component to a first package component using springs rather than rigid connectors alone, variations between the components due to warpage or thermal mismatch can be accounted for without unduly stressing the connections between the first package component and the second package component. Where the second package component produces more thermal energy, such as with a logic die or integrated voltage regulator device, the springs allow greater flexibility and robustness in the connectors during thermal cycling due to their being able to handle more CTE mismatch. Solder regions may be used in combination with the springs to provide fixed portions of the second package component to the first package component while allowing other portions to have movement. The springs allow movement without causing pad lift or solder crack issues which may cause failure in devices with only rigid connectors. The springs may also provide spacing functionality to maintain a minimum distance between components and may also provide better electro-migration resistance than solder connectors alone. Cost efficient imaging technology, such as x-ray imaging, may be used to verify the connections between the springs and solder regions.

One embodiment is a method including depositing solder paste over first contact pads of a first package component. The method also includes aligning spring connectors of a second package component to the solder paste. The method also includes reflowing the solder paste to electrically and physically couple the spring connectors of the second package component to the first contact pads of the first package component. In an embodiment, the method may include depositing an underfill extending between the first package component and the second package component. In an embodiment, the method may include depositing second solder paste over second contact pads of the second package component, aligning the spring connectors to the second solder paste, the spring connectors attached to a carrier, the spring connectors including microsprings, reflowing the second solder paste to electrically and physically couple the spring connectors to the second solder paste, and detaching the spring connectors from the carrier. In an embodiment, the method may include taking one or more x-ray images of joints between the spring connectors and solder paste. In an embodiment, the method may include, after finding one or more defective joints in the one or more x-ray images, performing a second reflow process to correct the one or more defective joints. In an embodiment, the method may include forming a solder ball over a second contact pad of the first package component, and during reflowing the solder paste, reflowing the solder ball to form a solder connection between the first package component and the second package component. In an embodiment, the second contact pad is at a corner of a package region of the first package component or the second contact pad is at a center of a package region of the first package component. In an embodiment, the spring connectors maintain a minimum distance between the first package component and the second package component, where warpage in the first package component or second package component causes one or more of the spring connectors to deform. In an embodiment, the first package component is an integrated fan out device and the second package component includes an integrated voltage regulator.

Another embodiment is a method including depositing solder paste over first contact pads and second contact pads of a workpiece, the workpiece including a carrier substrate, the first contact pads in a first device region, the second contact pads in a second device region. The method also includes aligning first connectors of a first device to the first contact pads and aligning second connectors of a second device to the second contact pads, the first connectors and the second connectors may include spring coils. The method also includes reflowing the solder paste to electrically and physically couple the first connectors to the first contact pads and the second connectors to the second contact pads. The method also includes removing the carrier substrate from the workpiece. The method also includes singulating the workpiece to form a first package and a second package, the first package including the first device, the second package including the second device. In an embodiment, the method may include depositing an underfill between the workpiece and the first device and between the workpiece and the second device, the underfill extending between the first device and the second device, the singulation cutting through the underfill. In an embodiment, the underfill encapsulates the spring coils, the spring coils comprising microsprings. In an embodiment, the method may include depositing solder over third contact pads, the third contact pads in the first device region, and reflowing the solder paste and the solder to electrically and physically couple the first device to the workpiece by the solder. In an embodiment, one of the third contact pads is interposed between two of the first contact pads. In an embodiment, the method may include depositing second solder paste over third contact pads of the first device, aligning a spring carrier to the second solder paste, reflowing the second solder paste to attach the spring coils from the spring carrier to the third contact pads by way of the solder paste, and cleaning flux residue off of the second solder paste following the reflowing of the second solder paste.

Another embodiment is a device including a first package component and a second package component. The second package component is electrically and physically coupled to the first package component by way of a plurality of spring coils, each of the plurality of spring coils extending from the first package component to the second package component. In an embodiment, the a first one of the spring coils rests at a different angle from a vertical line than a second one of the spring coils. In an embodiment, the device may include a first solder region interposed between the first package component and a first coil of the plurality of spring coils, and a second solder region interposed between the second package component and the first coil. In an embodiment, a solder region extends between the first package component and the second package component, the solder region adjacent a first coil of the plurality of spring coils. In an embodiment, the device may include an underfill disposed between the first package component and the second package component, the underfill extending between and contacting both the first package component and the second package component, the coil springs including microsprings.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
depositing solder paste over first contact pads of a first package component;
aligning spring connectors of a second package component to the solder paste; and
reflowing the solder paste to electrically and physically couple the spring connectors of the second package component to the first contact pads of the first package component.

2. The method of claim 1, further comprising:
depositing an underfill extending between the first package component and the second package component.

3. The method of claim 1, further comprising:
depositing second solder paste over second contact pads of the second package component;
aligning the spring connectors to the second solder paste, the spring connectors attached to a carrier, the spring connectors comprising microsprings;
reflowing the second solder paste to electrically and physically couple the spring connectors to the second solder paste; and
detaching the spring connectors from the carrier.

4. The method of claim 1, further comprising:
taking one or more x-ray images of joints between the spring connectors and solder paste.

5. The method of claim 4, further comprising:
after finding one or more defective joints in the one or more x-ray images, performing a second reflow process to correct the one or more defective joints.

6. The method of claim 1, further comprising:
forming a solder ball over a second contact pad of the first package component; and
during reflowing the solder paste, reflowing the solder ball to form a solder connection between the first package component and the second package component.

7. The method of claim 6, wherein the second contact pad is at a corner of a package region of the first package component or wherein the second contact pad is at a center of a package region of the first package component.

8. The method of claim 1, wherein the spring connectors maintain a minimum distance between the first package component and the second package component, wherein warpage in the first package component or second package component causes one or more of the spring connectors to deform.

9. The method of claim 1, wherein the first package component is an integrated fan out device and wherein the second package component includes an integrated voltage regulator.

10. A method comprising:
depositing solder paste over first contact pads and second contact pads of a workpiece, the workpiece including a carrier substrate, the first contact pads in a first device region, the second contact pads in a second device region;
aligning first connectors of a first device to the first contact pads and aligning second connectors of a second device to the second contact pads, the first connectors and the second connectors comprising spring coils;
reflowing the solder paste to electrically and physically couple the first connectors to the first contact pads and the second connectors to the second contact pads;
removing the carrier substrate from the workpiece; and
singulating the workpiece to form a first package and a second package, the first package including the first device, the second package including the second device.

11. The method of claim 10, further comprising:
depositing an underfill between the workpiece and the first device and between the workpiece and the second device, the underfill extending between the first device and the second device, the singulation cutting through the underfill.

12. The method of claim 11, wherein the underfill encapsulates the spring coils, the spring coils comprising microsprings.

13. The method of claim 10, further comprising:
depositing solder over third contact pads, the third contact pads in the first device region; and
reflowing the solder paste and the solder to electrically and physically couple the first device to the workpiece by the solder.

14. The method of claim 13, wherein the one of the third contact pads is interposed between two of the first contact pads.

15. The method of claim 10, further comprising:
depositing second solder paste over third contact pads of the first device;
aligning a spring carrier to the second solder paste;
reflowing the second solder paste to attach the spring coils from the spring carrier to the third contact pads by way of the solder paste; and
cleaning flux residue off of the second solder paste following the reflowing of the second solder paste.

16. A device comprising:
a first package component; and
a second package component electrically and physically coupled to the first package component by way of a plurality of spring coils, each of the plurality of spring coils extending from the first package component to the second package component.

17. The device of claim 16, wherein a first one of the spring coils rests at a different angle from a vertical line than a second one of the spring coils.

18. The device of claim 16, further comprising:
a first solder region interposed between the first package component and a first coil of the plurality of spring coils; and
a second solder region interposed between the second package component and the first coil.

19. The device of claim 16, further comprising a solder region extending between the first package component and the second package component, the solder region adjacent a first coil of the plurality of spring coils.

20. The device of claim 16, further comprising:
an underfill disposed between the first package component and the second package component, the underfill extending between and contacting both the first package component and the second package component, wherein the spring coils comprise micro springs.
